(19) United States
(12) Patent Application Publication
(10) Pub. No.: US 2010/0187493 A1
(43) Pub. Date: Jul. 29, 2010

(54) Semiconductor storage device and method of manufacturing the same

(75) Inventor: Shingo Takahashi, Kanagawa (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 12/654,979

(22) Filed: Jan. 12, 2010

(30) Foreign Application Priority Data
Jan. 29, 2009 (JP) 2009-017471

(51) Int. Cl. H01L 45/00; H01L 29/22; H01L 21/34

(52) U.S. Cl. 257/4; 257/43; 438/104; 257/E45.003; 257/E29.094; 257/E21.459

(57) ABSTRACT

Disclosed is a semiconductor storage device including a first electrode formed by being embedded in an insulating film formed on a substrate, a second electrode formed to be opposed to the first electrode, a storage layer formed between the first electrode and the second electrode, the storage layer being on a side of the first electrode, an ion source layer formed between the storage layer and the second electrode, and a diffusion prevention layer formed of a manganese oxide layer between the insulating film and the first electrode.

### BACKGROUND OF THE INVENTION

1. Field of the Invention

The present invention relates to a semiconductor storage device and a method of manufacturing the same.

2. Description of the Related Art

In an electronic apparatus such as a computer, a high-density DRAM that performs a high-speed operation is being widely used as a random access memory.

However, a manufacturing process of a DRAM is more complicated than that of a general logic circuit LSI or a signal processing LSI that is used for an electronic apparatus. As a result, a manufacturing cost of a DRAM is increased. Further, a DRAM is a volatile memory and loses its information stored, when the power is turned off. For this reason, a DRAM is necessary to be subjected to a constant refresh operation (i.e., operation of reading written information (data), re-amplifying the information, and writing it again).

In view of this, as non-volatile memories that do not lose stored information even when the power is turned off, a Fe-RAM (ferroelectric memory), an MRAM (magnetic memory), and the like have been proposed. In a case of using one of those memories, written information can be retained for a long time period, even when the power is not supplied. Further, in the case of using one of those memories, because of its non-volatility, the refresh operation is not necessary, and therefore power consumption can be reduced.

However, along with size reduction of a memory element that constitutes each memory cell, it becomes difficult for the above-mentioned non-volatile memory to secure its characteristics as a storage element. For this reason, it is difficult to reduce the size of an element to the limit of a design rule or a manufacturing process.

In view of this, as a memory having a structure suitable for the size reduction, there has been proposed a storage element of a new type. The storage element has a structure in which an ionic, conductor containing a certain metal is sandwiched between two electrodes. By causing the metal in the ionic conductor (ion source) to be contained into one of the two electrodes, the metal contained in the electrode diffuses into the ionic conductor as ions when a voltage is applied between the two electrodes. As a result, electric characteristics such as a resistance value and a capacitance of the ionic conductor are changed. With the use of the change of the characteristics, a memory device can be structured (see, for example, Japanese Patent Application Laid-open No. 2006-173267 and K. Aratani et al.: Proc. of IEEE IEDM 2007, p.p. 783-786).

FIG. 9 is a diagram showing a basic structure of a semiconductor storage device of a resistance change type.

As shown in FIG. 9, a first wiring 151 is formed in an insulating film 140 formed on a substrate 110. On the insulating film 140, a first insulating film 121 that covers the first wiring 151 is formed. The first insulating film 121 is formed of laminated films of a silicon carbon nitride film 122 and a silicon oxide (TEOS) film 123, for example.

In the first insulating film 121, a first opening portion 1220 that reaches the first wiring 151 is formed. In the first opening portion 1220, a first electrode 111 connected to the first wiring 151 is formed. The first electrode 111 is made of tungsten (W), tungsten nitride (WN), copper (Cu), or the like. A surface of the first electrode 111 and a surface of the first insulating film 121 are flattened so as to be approximately flush with each other.

On the first insulating film 121, a storage layer 112 that covers the first electrode 111 is formed. The storage layer 112 is made of an oxide of metal such as an oxide of tantalum, an oxide of niobium, an oxide of aluminum, an oxide of hafnium, and an oxide of zirconium, or made of a mixed material thereof.

On the storage layer 112, an ion source layer 113 is formed. The ion source layer 113 contains at least one of copper (Cu), silver (Ag), and zinc (Zn) and at least one of chalcogenide elements such as tellurium (Te), selenium (Se), and sulfur (S). For example, CuTe, GeSbTe, CuGeTe, AgGeTe, AgTe, ZnTe, ZnGeTe, CuS, CuGeS, CuSe, CuGeSe, or the like are contained. Further, boron (B), rare-earth elements, or silicon (Si) may be contained.

Further, on the ion source layer 113, a second insulating film 1230 is formed. In the second insulating layer 123, a second opening portion 124 that reaches the ion source layer 113 is formed in a position opposed to the first electrode 111. Further, through the second opening portion 124, a second electrode 114 is formed on the ion source layer 113 above the first electrode 111.

The semiconductor storage device 101 of the resistance change type in related art is structured as described above.

For further miniaturization of a device for the future, the use of copper (Cu) as an electrode material has been proposed in terms of filling performance. Specifically, a copper diffusion prevention layer (barrier metal layer) and a seed layer (copper power-feeding layer) are formed, and then copper is filled by plating, thereby producing an electrode by using a copper damascene process for forming a wiring.

In this case, a diffusion prevention layer is formed for a copper wiring of a first electrode. For the diffusion prevention layer, a general tantalum-based film such as tantalum (Ta) and tantalum nitride (TaN) and a general titanium-based film such as titanium (Ti) and titanium nitride (TiN) are used. In this case, the applicant of the present invention has revealed that a problem in that the tantalum-based film or the titanium-based film degrades the performance of the semiconductor storage device of the resistance change type. The performance degradation mainly occurs as reduction in the number of repetitive operations.

It is thought that the performance degradation arises from the diffusion at a time when a high electric field is applied to those metal materials. That is, the diffusion of the metals in the storage layer or in the ion source layer affects original characteristics of those layers, which may change the characteristics.

### SUMMARY OF THE INVENTION

There is a problem in that the use of a tantalum-based film or a titanium-based film for a material of a copper diffusion prevention layer causes performance degradation of a semiconductor storage device of a resistance change type.

In view of the above-mentioned circumstances, it is desirable to enable formation of a copper diffusion prevention layer by using a material that does not cause performance deterioration of a semiconductor storage device of a resistance change type.

According to an embodiment of the present invention, there is provided a semiconductor storage device including a first electrode, a second electrode, a storage layer, an ion source layer, and a diffusion prevention layer. The first electrode is formed by being embedded in an insulating film formed on a substrate.

The second electrode is formed to be opposed to the first electrode. The storage layer is formed between the first electrode and the second electrode, the storage layer being on a side of the first electrode. The ion source layer is formed between the storage layer and the second electrode. The diffusion prevention layer is formed of a manganese oxide layer between the insulating film and the first electrode.

According to another embodiment of the present invention, there is provided a semiconductor storage device including a first electrode, a second electrode, a storage layer, an ion source layer, and a diffusion prevention layer. The first electrode is formed by being embedded in an insulating film formed on a substrate. The second electrode is formed to be opposed to the first electrode. The storage layer is formed of a manganese oxide layer between the first electrode and the second electrode, the storage layer being on a side of the first electrode. The ion source layer is formed between the storage layer and the second electrode. The diffusion prevention layer is formed of at least one of a tungsten layer, a tungsten nitride layer, a ruthenium layer, and a ruthenium nitride layer, and the diffusion prevention layer is formed between the insulating film and the first electrode and connected with the storage layer.

According to another embodiment of the present invention, there is provided a method of manufacturing a semiconductor storage device including forming an opening portion in an insulating film formed on a substrate, forming a seed layer on an inner surface of the opening portion, the seed layer being formed of a copper-manganese alloy layer, embedding a copper film in the opening portion through the seed layer and forming the copper film on the insulating film, forming a manganese oxide layer in a surface of the seed layer on a side of the insulating film by a heat treatment, forming a first electrode in the opening portion through a diffusion prevention layer by removing the copper film redundant on the insulating film and the manganese oxide layer formed on the copper film, the first electrode being formed of the copper film, the diffusion prevention layer being formed of the manganese oxide layer, forming a storage layer on the first electrode and the insulating layer, forming an ion source layer on the storage layer, and forming a second electrode on the ion source layer.

According to another embodiment of the present invention, there is provided a method of manufacturing a semiconductor storage device including forming an opening portion in an insulating film formed on a substrate, forming a seed layer on an inner surface of the opening portion, the seed layer being formed of a copper-manganese alloy layer, embedding a copper film in the opening portion through the seed layer and forming the copper film on the insulating film, forming a manganese oxide layer in the surface of the seed layer on a side of the insulating film by a heat treatment, forming a first electrode in the opening portion through a diffusion prevention layer by removing the copper film redundant on the insulating film and the manganese oxide layer formed on the copper film, the first electrode being formed of the copper film, the diffusion prevention layer being formed of the manganese oxide layer, the diffusion prevention layer being formed of the manganese oxide layer, forming a manganese oxide layer on a surface of the first electrode by the heat treatment, forming a storage layer on the insulating film and on the first electrode through the manganese oxide layer formed on the surface of the first electrode, forming an ion source layer on the storage layer, and forming a second electrode on the ion source layer.

According to another embodiment of the present invention, there is provided a method of manufacturing a semiconductor storage device including forming an opening portion in an insulating film formed on a substrate, forming a seed layer on an inner surface of the opening portion, the seed layer being formed of a copper-manganese alloy layer, embedding a copper film in the opening portion through the seed layer and forming the copper film on the insulating film, forming a manganese oxide layer in the surface of the seed layer on a side of the insulating film by a heat treatment, forming a first electrode in the opening portion through a diffusion prevention layer by removing the copper film redundant on the insulating film and the manganese oxide layer formed on the copper film, the first electrode being formed of the copper film, the diffusion prevention layer being formed of the manganese oxide layer, forming a storage layer formed of a manganese oxide layer on a surface of the first electrode by the heat treatment, forming an ion source layer on the storage layer, and forming a second electrode on the ion source layer.

According to another embodiment of the present invention, there is provided a method of manufacturing a semiconductor storage device including forming an opening portion in an insulating film formed on a substrate, forming a diffusion prevention layer on an inner surface of the opening portion, the diffusion prevention layer being formed of at least one of a tungsten layer, a tungsten nitride layer, a zirconium layer, a zirconium nitride layer, a hafnium layer, a hafnium nitride layer, a ruthenium layer, and a ruthenium nitride layer, forming a seed layer on the inner surface of the opening portion through the diffusion prevention layer, the seed layer being formed of a copper-manganese alloy layer, embedding a copper film in the opening portion through the seed layer and forming the copper film on the insulating film, forming a first electrode in the opening portion through the diffusion prevention layer by removing the copper film, the seed layer, and the diffusion prevention layer that are redundant on the insulating film, the first electrode being formed of the seed layer and the copper film, forming a storage layer formed of a manganese oxide layer on a surface of the first electrode by a heat treatment, the manganese oxide layer being connected with the diffusion prevention layer, forming an ion source layer on the insulating film and on the storage layer, and forming a second electrode on the ion source layer.

In the semiconductor storage device according to the embodiments of the present invention, the diffusion prevention layer is made of the manganese oxide. Therefore, even when a high electric field is applied to the diffusion prevention layer, manganese is prevented from diffusing in the storage layer or the ion source layer. Thus, there is the advantage in that the performance degradation of the semiconductor storage device can be suppressed.

In the method of manufacturing the semiconductor storage device according to the embodiments of the present invention, the diffusion prevention layer is made of the manganese oxide. Therefore, even when a high electric field is applied to the diffusion prevention layer, manganese is prevented from diffusing in the storage layer or the ion source layer. Thus, there is the advantage in that the semiconductor storage device whose performance is suppressed to be degraded can be manufactured.

These and other objects, features and advantages of the present invention will become more apparent in light of the following detailed description of best mode embodiments thereof, as illustrated in the accompanying drawings.

### BRIEF DESCRIPTION OF DRAWINGS

FIG. 1 is a schematic cross-sectional view showing an example of a semiconductor storage device according to a first embodiment of the present invention;

FIG. 2 is a schematic cross-sectional view showing an example of a semiconductor storage device according to a second embodiment of the present invention;

FIG. 3 is a schematic cross-sectional view showing an example of a semiconductor storage device according to a third embodiment of the present invention;

FIG. 4 is a schematic cross-sectional view showing an example of a semiconductor storage device according to a fourth embodiment of the present invention;

FIG. 5 are manufacturing-process cross-sectional views showing an example of a method of manufacturing a semiconductor storage device according to a fifth embodiment of the present invention;

FIG. 6 are manufacturing-process cross-sectional views showing an example of a method of manufacturing a semiconductor storage device according to a sixth embodiment of the present invention;

FIG. 7 are manufacturing-process cross-sectional views showing an example of a method of manufacturing a semiconductor storage device according to a seventh embodiment of the present invention;

FIG. 8 are manufacturing-process cross-sectional views showing an example of a method of manufacturing a semiconductor storage device according to an eighth embodiment of the present invention; and

FIG. 9 is a schematic cross-sectional view showing an example of a semiconductor storage device in related art.

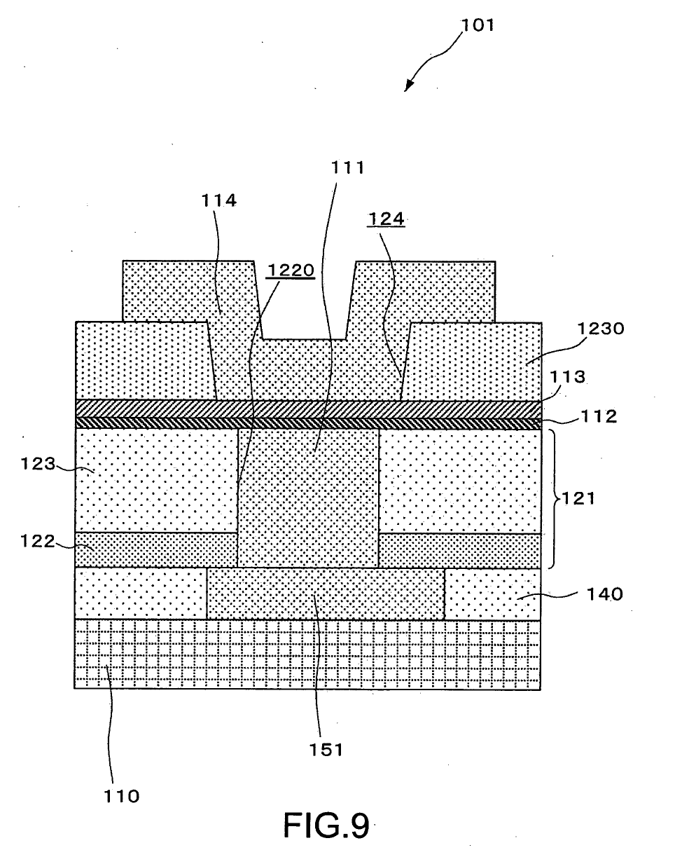

### DESCRIPTION OF PREFERRED EMBODIMENTS

### 1. First Embodiment

### One Example of Structure of Semiconductor Storage Device

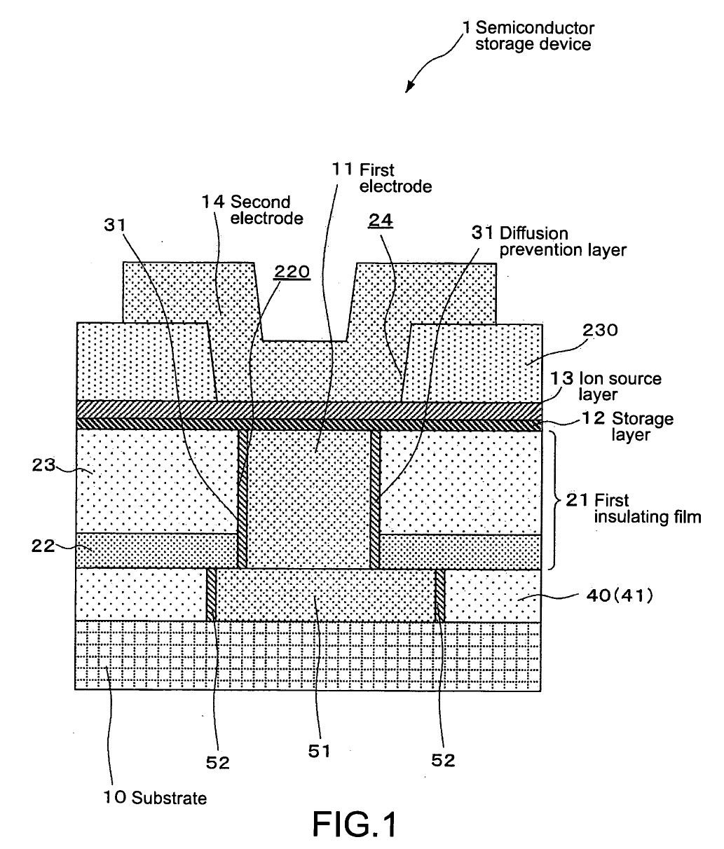

An example of a semiconductor storage device according to a first embodiment of the present invention will be described with reference to a cross-sectional view of a schematic structure shown in FIG. 1.

As shown in FIG. 1, a first wiring 51 is formed in, e.g., an insulating film 41 in an uppermost layer of an insulating film 40 formed on a substrate 10. The first wiring 51 is formed of a copper wiring. On each of side portions of the first wiring 51, a diffusion prevention layer 52 is formed.

On the insulating film 40, a first insulating film 21 that covers the first wiring 51 is formed. The first insulating film 21 is formed of laminated films of a silicon carbon nitride film 22 and a silicon oxide (TEOS) film 23, for example. In addition to the silicon oxide film and the silicon carbon nitride film, the following films can be used for the first insulating film 21. For example, an inorganic insulating film such as a silicon nitride film, a silicon oxynitride film, and a silicon fluoride oxide film can be used. In addition, an insulating film used for a general semiconductor device, e.g., a fluorine-based organic insulating material such as an amorphous fluorine resin and a polyarylether-fluoride-based resin, an aromatic organic insulating material such as polyarylether, poly-para-xylylene, and polyimide, or the like can be used.

In the first insulating film 21, a first opening portion 220 that reaches the first wiring 51 is formed. In the first opening portion 220, a first electrode 11 connected to the first wiring 51 is formed through a diffusion prevention layer 31.

The first electrode 11 is made of copper (Cu), for example. A surface of the first electrode 11 and a surface of the first insulating film 21 are flattened so as to be approximately flush with each other.

The diffusion prevention layer 31 is formed of a manganese oxide. In order to give the manganese oxide an oxidation prevention function for copper, the manganese oxide only has to have a thickness of 1 nm or more, desirably, 2 nm or more. If the thickness is excessively increased, a volume occupied by the first electrode 11 is reduced, which increases the resistance. Therefore, it is desirable to set the thickness of the manganese oxide to 5 nm or less.

It should be noted that the diffusion prevention layer 31 may be formed of a tungsten-based barrier metal layer such as a tungsten layer and a tungsten nitride layer, a zirconium-based barrier metal layer such as a zirconium layer and a zirconium nitride layer, a hafnium-based barrier metal layer such as a hafnium layer and a hafnium nitride layer, or a ruthenium-based barrier metal layer such as a ruthenium layer or a ruthenium nitride layer, instead of the manganese oxide layer.

On the first insulating layer 21, a storage layer 12 that covers the surface of the first electrode 11 is formed. The storage layer 12 is made of an oxide of metal, such as an oxide of tantalum, an oxide of niobium, an oxide of aluminum, an oxide of hafnium, and an oxide of zirconium, or made of a mixed material thereof. It is desirable to set the storage layer 12 to be thin, specifically, 2 nm or less, desirably, 1 nm or less, more desirably, 0.5 nm or less in thickness.

On the storage layer 12, an ion source layer 13 is formed. The ion source layer 13 contains at least one of copper (Cu), silver (Ag), and zinc (Zn) and at least one of chalcogenide elements such as tellurium (Te), selenium (Se), and sulfur (S). For example, CuTe, GeSbTe, CuGeTe, AgGeTe, AgTe, ZnTe, ZnGeTe, CuS, CuGeS, CuSe, CuGeSe, or the like are contained. Further, boron (B), rare-earth elements, or silicon (Si) may be contained.

Accordingly, the ion source layer 13 contains at least one of the elements of Cu, Ag, and Zn. That is, the ion source layer 13 serves as a layer that supplies ions of at least one of Cu, Ag, and Zn to the storage layer 12 or receives the ions supplied to the storage layer 12.

In addition, on the ion source layer 13, a second insulating film 230 is formed. In the second insulating film 230, a second opening portion 24 that reaches the ion source layer 13 is formed at a position opposed to the first electrode 11. The second insulating film 230 can be made of a material similar to that capable of being used as the first insulating film 21.

Through the second opening portion 24, a second electrode 14 is formed on the ion source layer 13. The second electrode 14 can be made of a conductive material similar to that of the first electrode 11.

As described above, a semiconductor storage device 1 of the resistance change type is structured.

Hereinafter, operations of the semiconductor storage device 1 will be described.

The ion source layer 13 contains at least one element of Cu, Ag, and Zn. That is, the ion source layer 13 supplies at least one kind of ions out of Cu, Ag, and Zn to the storage layer 12, or receives ions supplied to the storage layer 12. In the following description, a case where the ion source layer 13 is formed of CuTe is shown as an example.

To the ion source layer 13, a positive potential (+potential) is applied, to cause the first electrode 11 to be negative. With this operation, Cu from the ion source layer 13 is ionized and diffused in the storage layer 12, and is bonded with electrons to be deposited on the first electrode 11 side, or remains in the storage layer 12 with the Cu ions being diffused. Of course, in a case where the ion source layer 13 contains Ag and Zn, those elements are ionized and behave like Cu.

As a result, in the storage layer 12, a current path that contains a large amount of Cu is formed. Alternatively, a large number of defects due to Cu are formed in the storage layer 12, which reduces a resistance value of the storage layer 12. Of course, Ag and Zn behave like Cu.

The layers other than the storage layer 12, i.e., the ion source layer 13, the first electrode 11, the second electrode 14, and the like originally have smaller resistance values than the storage layer 12 prior to recording. Therefore, by setting the resistance value of the recording layer 12 to be low, the entire resistance value of the main portions (the first electrode 11, storage layer 12, ion source layer 13, and second electrode 14) of the semiconductor storage device 1 can be reduced.

After that, when a positive voltage is removed to eliminate a voltage applied to the semiconductor storage device 1, the state of the low resistance of the semiconductor storage device 1 can be maintained. As a result, information can be recorded. In a case where a storage device capable of recording information only once, i.e., a so-called PROM is used, the recording is completed only by the recording process described above.

On the other hand, for application to an erasable storage device, i.e., a so-called RAM, EEPROM, or the like, an erasing process is necessary.

In the erasing process, a negative potential (− potential) is applied to the ion source layer 13 that contains Cu, Ag, or Zn, thereby causing the first electrode 11 to be positive. As a result, Cu, Ag, or Zn that forms an impurity level or the current path formed in the storage layer 12 is ionized and moved in the storage layer 12, and returns to the ion source layer 13.

As a result, the defects or the current path formed by Cu, Ag, or Zn is disappeared, which increases the resistance value of the storage layer 12. The layers other than the storage layer 12, i.e., the ion source layer 13, the first electrode 11, the second electrode 14, and the like originally have smaller resistance values. Therefore, by setting the resistance value of the recording layer 12 to be high, the entire resistance value of the main portions (the first electrode 11, storage layer 12, ion source layer 13, and second electrode 14) of the semiconductor storage device 1 can be increased.

After that, when a negative voltage is removed to eliminate a voltage applied to the semiconductor storage device 1, the state of the high resistance of the semiconductor storage device 1 can be maintained. As a result, the information can be erased.

By repeatedly performing the above-described processes, the information can be recorded (written) on the semiconductor storage device 1, or the information recorded can be erased repeatedly.

Because the diffusion prevention layer 31 of the semiconductor storage device 1 is formed of the manganese oxide, even when a high electric field is applied to the diffusion prevention layer 31, manganese is prevented from diffusing in the storage layer 12 or the ion source layer 13. Therefore, the performance degradation of the semiconductor storage device 1 can be suppressed, and there is an advantage in that the high-performance semiconductor storage device of the resistance change type can be provided.

### 2. Second embodiment

### One Example of Structure of Semiconductor Storage Device

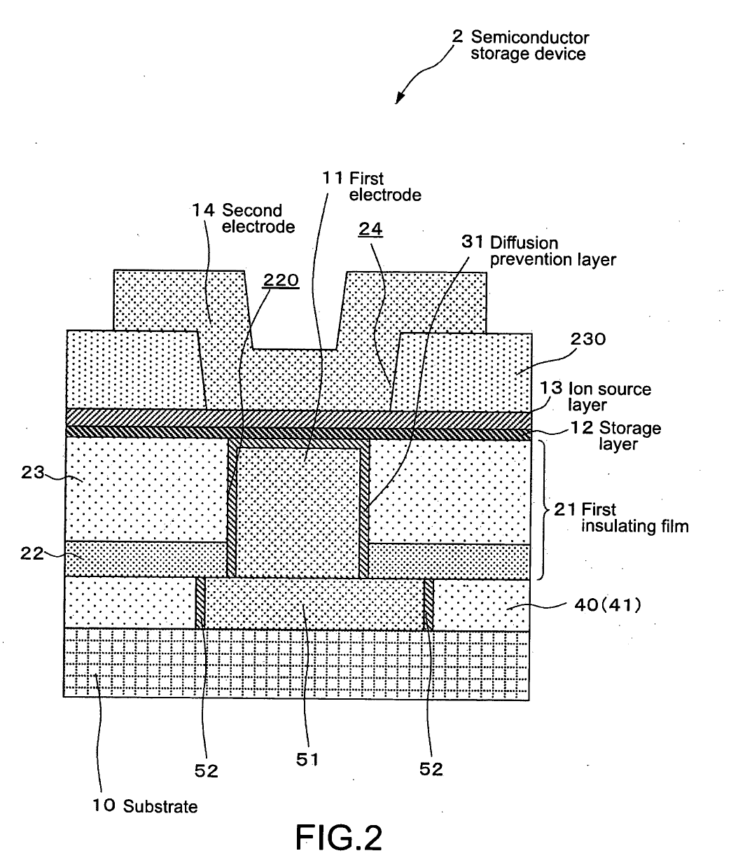

An example of a semiconductor storage device according to a second embodiment of the present invention will be described with reference to a cross-sectional view of a schematic structure shown in FIG. 2.

As shown in FIG. 2, the first wiring 51 is formed in, e.g., the insulating film 41 in the uppermost layer of the insulating film 40 formed on the substrate 10. The first wiring 51 is formed of a copper wiring, for example. On each of side portions of the first wiring 51, the diffusion prevention layer 52 is formed.

On the insulating film 40, the first insulating film 21 that covers the first wiring 51 is formed. The first insulating film 21 is formed of laminated films of the silicon carbon nitride film 22 and the silicon oxide (TEOS) film 23, for example. In addition to the silicon oxide film and the silicon carbon nitride film, the following materials can be used for the first insulating film 21. For example, the inorganic insulating film such as the silicon nitride film, the silicon oxynitride film, the silicon fluoride oxide film, an aluminum oxide film (Al₂O₃), a tantalum oxide (Ta₂O₅), a hafnium oxide (HfO₂), and a zirconium oxide (ZrO₂) can be used. In addition, an insulating film used for a general semiconductor device, e.g., the fluorine-based organic insulating material such as the amorphous fluorine resin and the polyarylether-fluoride-based resin, the aromatic organic insulating material such as polyarylether, poly-para-xylylene, and polyimide, or the like can be used.

In the first insulating film 21, the first opening portion 220 that reaches the first wiring 51 is formed. In the first opening portion 220, the first electrode 11 connected to the first wiring 51 is formed through the diffusion prevention layer 31. The diffusion prevention layer 31 is also formed on the surface of the first electrode 11.

The first electrode 11 is made of tungsten (W), tungsten nitride (WN), or copper (Cu), for example. The surface of the first electrode 11, on which the diffusion prevention layer 31 is formed, and the surface of the first insulating film 21 are flattened so as to be approximately flush with each other.

The diffusion prevention layer 31 is formed of the manganese oxide. In order to give the manganese oxide an oxidation prevention function for copper, the manganese oxide only has to have a thickness of 1 nm or more, desirably, 2 nm or more. If the thickness is excessively increased, the volume occupied by the first electrode 11 is reduced, which increases the resistance. Therefore, it is desirable to set the thickness of the manganese oxide to 5 nm or less.

It should be noted that the diffusion prevention layer 31 may be formed of the tungsten-based barrier metal layer such as the tungsten layer and the tungsten nitride layer, the zirconium-based barrier metal layer such as the zirconium layer and the zirconium nitride layer, the hafnium-based barrier metal layer such as the hafnium layer and the hafnium nitride layer, or the ruthenium-based barrier metal layer such as the ruthenium layer or the ruthenium nitride layer, instead of the manganese oxide layer.

On the first insulating layer 21, the storage layer 12 that covers the diffusion prevention layer 31 formed on the surface of the first electrode 11 is formed. The storage layer 12 is made of the oxide of metal, such as the oxide of tantalum, the oxide of niobium, the oxide of aluminum, the oxide of hafnium, and the oxide of zirconium, or made of the mixed material thereof. It is desirable to set the storage layer 12 to be thin, specifically, 2 nm or less, desirably, 1 nm or less, more desirably, 0.5 nm or less in thickness.

On the storage layer 12, the ion source layer 13 is formed. The ion source layer 13 contains at least one of copper (Cu), silver (Ag), and zinc (Zn) and at least one of chalcogenide elements such as tellurium (Te), selenium (Se), and sulfur (S). For example, CuTe, GeSbTe, CuGeTe, AgGeTe, AgTe, ZnTe, ZnGeTe, CuS, CuGeS, CuSe, CuGeSe, or the like are contained. Further, boron (B), rare-earth elements, or silicon (Si) may be contained.

Accordingly, the ion source layer 13 contains at least one of the elements of Cu, Ag, and Zn. That is, the ion source layer 13 serves as a layer that supplies ions of at least one of Cu, Ag, and Zn to the storage layer 12 or receives the ions supplied to the storage layer 12.

In addition, on the ion source layer 13, the second insulating film 230 is formed. In the second insulating film 230, the second opening portion 24 that reaches the ion source layer 13 is formed at a position opposed to the first electrode 11. The second insulating film 230 can be made of a material similar to that capable of being used as the first insulating film 21.

Through the second opening portion 24, the second electrode 14 is formed on the ion source layer 13 above the first electrode 11. The second electrode 14 can be made of a conductive material similar to that of the first electrode 11.

As described above, a semiconductor storage device 2 of the resistance change type is structured.

Operations of the semiconductor storage device 2 are similar to those of the semiconductor storage device 1. The diffusion prevention layer 31 formed on the surface of the first electrode 11 also has the function of the storage layer 12. Therefore, it is desirable to set the diffusion prevention layer 31 formed on the surface of the first electrode 11 to be thin as much as possible.

The diffusion prevention layer 31 of the semiconductor storage device 2 is formed of the manganese oxide. Therefore, even when a high electric field is applied to the diffusion prevention layer 31, manganese is prevented from diffusing in the storage layer 12 or the ion source layer 13. Therefore, the performance degradation of the semiconductor storage device 2 can be suppressed, and there is an advantage in that the high-performance semiconductor storage device of the resistance change type can be provided.

In addition, the storage layer 12 is made of the oxide of metal and therefore contains oxygen. But, the diffusion prevention layer 31 is formed between the surface of the first electrode 11 and the storage layer 12, thereby making it possible to prevent the diffusion of oxygen from the storage layer 12 to the first electrode 11.

### 3. Third Embodiment

### One Example of Structure of Semiconductor Storage Device

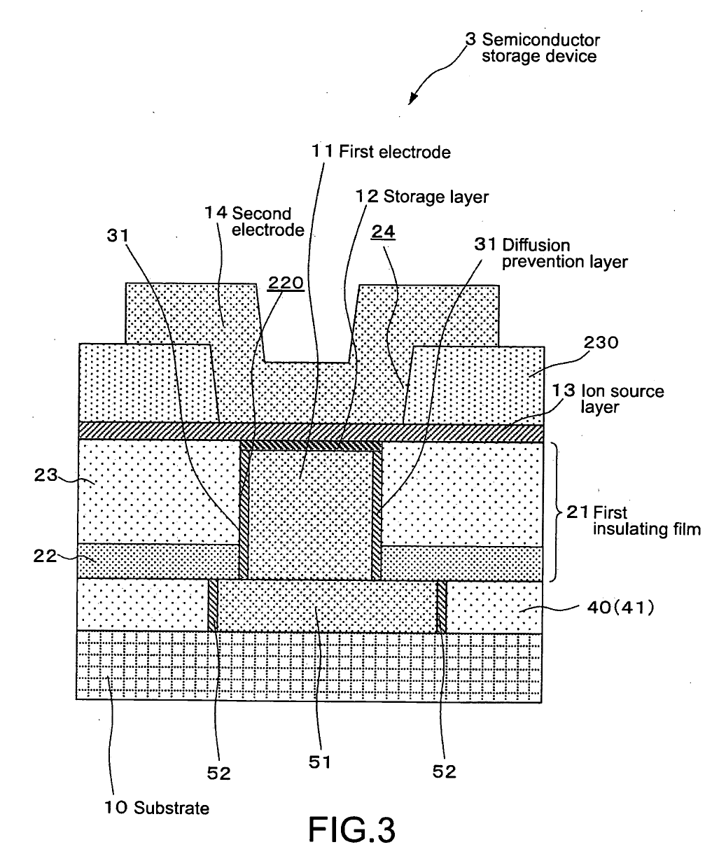

An example of a semiconductor storage device according to a third embodiment of the present invention will be described with reference to a cross-sectional view of a schematic structure shown in FIG. 3.

As shown in FIG. 3, the first wiring 51 is formed in, e.g., the insulating film 41 in the uppermost layer of the insulating film 40 formed on the substrate 10. The first wiring 51 is formed of a copper wiring, for example. On each of side portions of the first wiring 51, the diffusion prevention layer 52 is formed.

On the insulating film 40, the first insulating film 21 that covers the first wiring 51 is formed. The first insulating film 21 is formed of laminated films of the silicon carbon nitride film 22 and the silicon oxide (TEOS) film 23, for example. In addition to the silicon oxide film and the silicon carbon nitride film, the following films can be used for the first insulating film 21. For example, the inorganic insulating film such as the silicon nitride film, the silicon oxynitride film, the silicon fluoride oxide film, an aluminum oxide film (Al₂O₃), a tantalum oxide (Ta₂O₅), a hafnium oxide (HfO₂), and a zirconium oxide (ZrO₂) can be used. In addition, an insulating film used for a general semiconductor device, e.g., the fluorine-based organic insulating material such as the amorphous fluorine resin and the polyarylether-fluoride-based resin, the aromatic organic insulating material such as polyarylether, poly-para-xylylene, and polyimide, or the like can be used.

In the first insulating film 21, the first opening portion 220 that reaches the first wiring 51 is formed. In the first opening portion 220, the first electrode 11 connected to the first wiring 51 is formed through the diffusion prevention layer 31.

The first electrode 11 is made of tungsten (W), tungsten nitride (WN), or copper (Cu), for example. The surface of the first electrode 11 and the surface of the first insulating film 21 are flattened sous to be approximately flush with each other.

The diffusion prevention layer 31 is formed of the manganese oxide. In order to give the manganese oxide an oxidation prevention function for copper, the manganese oxide only has to have a thickness of 1 nm or more, desirably, 2 nm or more. If the thickness is excessively increased, the volume occupied by the first electrode 11 is reduced, which increases the resistance. Therefore, it is desirable to set the thickness of the manganese oxide to 5 nm or less.

It should be noted that the diffusion prevention layer 31 may be formed of the tungsten-based barrier metal layer such as the tungsten layer and the tungsten nitride layer, the zirconium-based barrier metal layer such as the zirconium layer and the zirconium nitride layer, the hafnium-based barrier metal layer such as the hafnium layer and the hafnium nitride layer, or the ruthenium-based barrier metal layer such as the ruthenium layer or the ruthenium nitride layer, instead of the manganese oxide layer.

On the surface of the first electrode 11, the storage layer 12 is formed. The storage layer 12 is made of, for example, the manganese oxide as in the case of the diffusion prevention layer 31. It is desirable to set the storage layer 12 to be thin, specifically, 2 nm or less, desirably, 1 nm or less, more desirably, 0.5 nm or less in thickness.

On the storage layer 12, the ion source layer 13 is formed. The ion source layer 13 contains at least one of copper (Cu), silver (Ag), and zinc (Zn) and at least one of chalcogenide elements such as tellurium (Te), selenium (Se), and sulfur (S). For example, CuTe, GeSbTe, CuGeTe, AgGeTe, AgTe, ZnTe, ZnGeTe, CuS, CuGeS, CuSe, CuGeSe, or the like are contained. Further, boron (B), rare-earth elements, or silicon (Si) may be contained.

Accordingly, the ion source layer 13 contains at least one of the elements of Cu, Ag, and Zn. That is, the ion source layer 13 serves as a layer that supplies ions of at least one of Cu, Ag, and Zn to the storage layer 12 or receives the ions supplied to the storage layer 12.

In addition, on the ion source layer 13, the second insulating film 230 is formed. In the second insulating film 230, the second opening portion 24 that reaches the ion source layer 13 is formed at a position opposed to the first electrode 11. The second insulating film 230 can be made of a material similar to that capable of being used as the first insulating film 21.

Through the second opening portion 24, the second electrode 14 is formed on the ion source layer 13 above the first electrode 11. The second electrode 14 can be made of a conductive material similar to that of the first electrode 11.

As described above, a semiconductor storage device 3 of the resistance change type is structured.

Operations of the semiconductor storage device 3 are similar to those of the semiconductor storage device 1 of the first embodiment.

The diffusion prevention layer 31 of the semiconductor storage device 3 is formed of the manganese oxide. Therefore, even when a high electric field is applied to the diffusion prevention layer 31, manganese is prevented from diffusing in the storage layer 12 or the ion source layer 13. Therefore, the performance degradation of the semiconductor storage device 3 can be suppressed, and there is an advantage in that the high-performance semiconductor storage device of the resistance change type can be provided.

### 4. Fourth Embodiment

### One Example of Structure of Semiconductor Storage Device

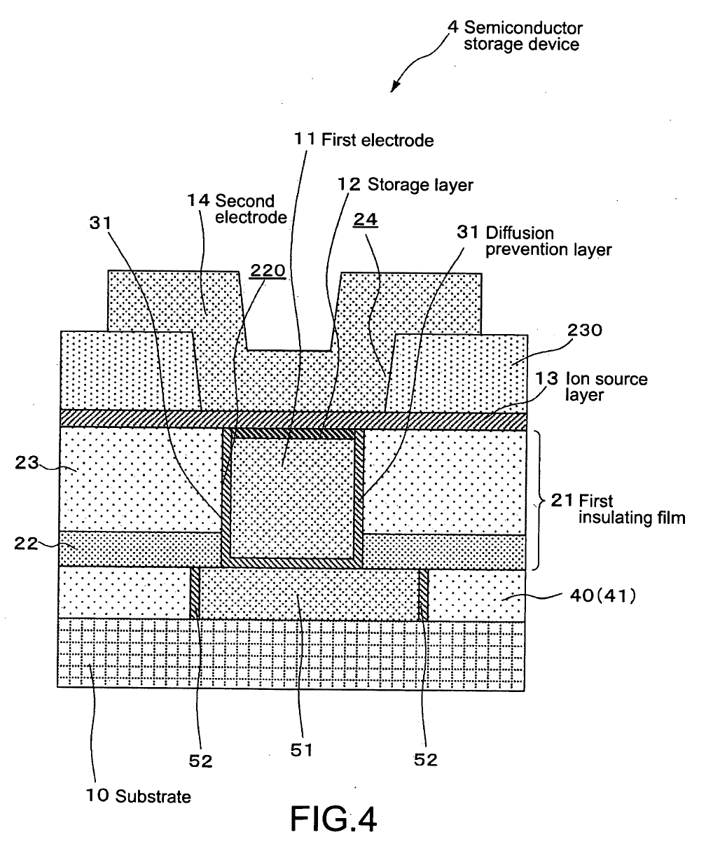

An example of a semiconductor storage device according to a fourth embodiment of the present invention will be described with reference to a cross-sectional view of a schematic structure shown in FIG. 4.

As shown in FIG. 4, the first wiring 51 is formed in, e.g., the insulating film 41 in the uppermost layer of the insulating film 40 formed on the substrate 10. The first wiring 51 is formed of a copper wiring, for example. On each of side portions of the first wiring 51, the diffusion prevention layer 52 is formed.

On the insulating film 40, the first insulating film 21 that covers the first wiring 51 is formed. The first insulating film 21 is formed of laminated films of the silicon carbon nitride film 22 and the silicon oxide (TEOS) film 23, for example. In addition to the silicon oxide film and the silicon carbon nitride film, the following films can be used for the first insulating film 21. For example, the inorganic insulating film such as the silicon nitride film, the silicon oxynitride film, the silicon fluoride oxide film, an aluminum oxide film (Al₂O₃), a tantalum oxide (Ta₂O₅), a hafnium oxide (HfO₂), and a zirconium oxide (ZrO₂) can be used. In addition, an insulating film used for a general semiconductor device, e.g., the fluorine-based-organic insulating material such as the amorphous fluorine resin and the polyarylether-fluoride-based resin, the aromatic organic insulating material such as polyarylether, poly-para-xylylene, and polyimide, or the like can be used.

In the first insulating film 21, the first opening portion 220 that reaches the first wiring 51 is formed. In the first opening portion 220, the first electrode 11 connected to the first wiring 51 is formed through the diffusion prevention layer 31.

The first electrode 11 is made of tungsten (W), tungsten nitride (WN), or copper (Cu), for example. The surface of the first electrode 11 and the surface of the first insulating film 21 are flattened so as to be approximately flush with each other.

The diffusion prevention layer 31 is formed of the tungsten-based barrier metal layer such as the tungsten layer and the tungsten nitride layer, the zirconium-based barrier metal layer such as the zirconium layer and the zirconium nitride layer, the hafnium-based barrier metal layer such as the hafnium layer and the hafnium nitride layer, or the ruthenium-based barrier metal layer such as the ruthenium layer or the ruthenium nitride layer. For the barrier metal layer, a tantalum-based material such as tantalum and tantalum nitride or a titanium-based material such as titanium and titanium nitride is not used.

On the surface of the first electrode 11, the storage layer 12 is formed. The storage layer 12 is made of the manganese oxide. It is desirable to set the storage layer 12 to be thin, specifically, 2 nm or less, desirably, 1 nm or less, more desirably, 0.5 nm or less in thickness.

On the storage layer 12, the ion source layer 13 is formed. The ion source layer 13 contains at least one of copper (Cu), silver (Ag), and zinc (Zn) and at least one of chalcogenide elements such as tellurium (Te), selenium (Se), and sulfur (S). For example, CuTe, GeSbTe, CuGeTe, AgGeTe, AgTe, ZnTe, ZnGeTe, CuS, CuGeS, CuSe, CuGeSe, or the like are contained. Further, boron (B), rare-earth elements, or silicon (Si) may be contained.

Accordingly, the ion source layer 13 contains at least one of the elements of Cu, Ag, and Zn. That is, the ion source layer 13 serves as a layer that supplies ions of at least one of Cu, Ag, and Zn to the storage layer 12 or receives the ions supplied to the storage layer 12.

In addition, on the ion source layer 13, the second insulating film 230 is formed. In the second insulating film 230, the second opening portion 24 that reaches the ion source layer 13 is formed at a position opposed to the first electrode 11. The second insulating film 230 can be made of a material similar to that capable of being used as the first insulating film 21.

Through the second opening portion 24, the second electrode 14 is formed on the ion source layer 13 above the first electrode 11. The second electrode 14 can be made of a conductive material similar to that of the first electrode 11.

As described above, a semiconductor storage device 4 of the resistance change type is structured.

Operations of the semiconductor storage device 4 are similar to those of the semiconductor storage device 1 of the first embodiment.

The diffusion prevention layer 31 of the semiconductor storage device 4 is formed of the tungsten (W)-based barrier metal layer. Therefore, even when a high electric field is applied to the diffusion prevention layer 31, tungsten is prevented from diffusing in the storage layer 12 or the ion source layer 13. Therefore, the performance degradation of the semiconductor storage device 4 can be suppressed, and there is an advantage in that the high-performance semiconductor storage device of the resistance change type can be provided.

### 5. Fifth Embodiment

### One Example of Method of Manufacturing Semiconductor Storage Device

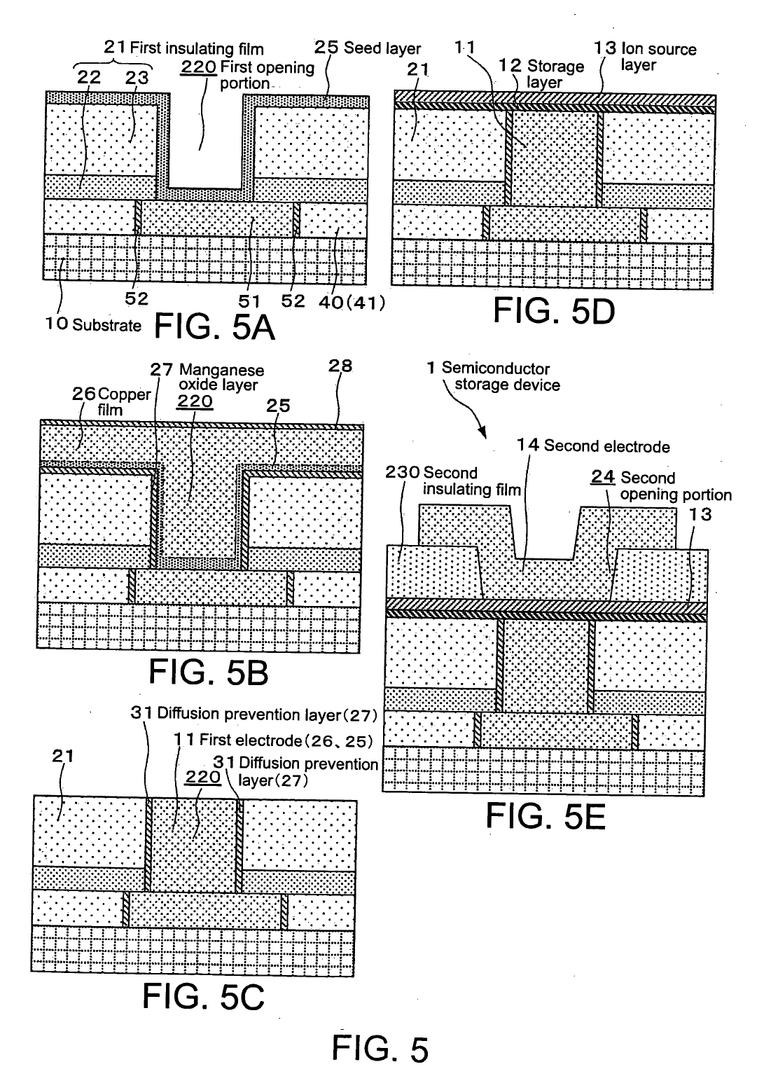

A description will be given on an example of a method of manufacturing a semiconductor storage device according to a fifth embodiment of the present invention, with reference to manufacturing-process cross-sectional views of FIGS. 5A to 5E. FIGS. 5A to 5E show a method of manufacturing the semiconductor storage device 1 described above with reference to FIG. 1.

As shown in FIG. 5A, the first wiring 51 is formed in, e.g., the insulating film 41 in the uppermost layer of the insulating film 40 formed on the substrate 10. The first wiring 51 is formed of a copper wiring, for example. On each of side portions of the first wiring 51, the diffusion prevention layer 52 is formed.

On the insulating film 40, the first insulating film 21 that covers the first wiring 51 is formed. The first insulating film 21 is formed of the laminated films of the silicon carbon nitride film 22 and the silicon oxide (TEOS) film 23, for example. In addition to the silicon oxide film and the silicon carbon nitride film, the following films can be used for the first insulating film 21. For example, the inorganic insulating film such as the silicon nitride film, the silicon oxynitride film, the silicon fluoride oxide film, the aluminum oxide film (Al₂O₃), a tantalum oxide (Ta₂O₅), the hafnium oxide (HfO₂), and the zirconium oxide (ZrO₂) can be used. In addition, an insulating film used for a general semiconductor device, e.g., the fluorine-based organic insulating material such as the amorphous fluorine resin and the polyarylether-fluoride-based resin, the aromatic organic insulating material such as polyarylether, poly-para-xylylene, and polyimide, or the like can be used.

In the first insulating film 21, the first opening portion 220 that reaches the first wiring 51 is formed. The first opening portion 220 is formed by an etching that uses a resist mask, which is generally performed in a general semiconductor manufacturing process.

Further, on an inner surface of the first opening portion 220, a seed layer 25 formed of a copper-manganese alloy layer is formed.

The seed layer 25 is made of a copper-manganese alloy by a sputtering method, for example. Specifically, the seed layer 25 is formed to have a thickness of 30 nm to 80 nm by the sputtering method using a copper-manganese (Cu—Mn) alloy target containing Mn of about 2 at % to 10 ata, for example.

Next, as shown in FIG. 5B, by a plating method, a copper film 26 is filled in the first opening portion 220 through the seed layer 25, and the copper film 26 is formed on the first insulating film 21.

Subsequently, a heat treatment is performed, with the result that a manganese oxide layer 27 is self-formed on the surface of the seed layer 25 on the first insulating film 21 side. The heat treatment is performed at 300° C. to 400° C., for example. Specifically, for example, the heat treatment is performed at 350° C. for 30 minutes.

In order to give the manganese oxide layer 27 an oxidation prevention function for copper, the manganese oxide layer only has to have a thickness of 1 nm or more, desirably, 2 nm or more. If the thickness is excessively increased, the volume occupied by the first electrode 11 is reduced, which increases the resistance. Therefore, it is desirable to set the thickness of the manganese oxide layer 27 to 5 nm or less.

In addition, in the heat treatment, extra manganese (Mn) reacts with oxygen in an atmosphere, to form a manganese oxide layer 28 on a surface of the copper film 26 formed by the plating. Therefore, almost no manganese (Mn) remains in the seed layer 25 and the copper film 26 in the first opening portion 220. Accordingly, a significant increase in wiring resistance due to residual manganese is prevented.

Next, as shown in FIG. 5C, the extra copper film 26 (including the seed layer 25) formed on the first insulating film 21 and the manganese oxide layer 28 formed on the surface of the copper film 26 are removed. The removal process is performed by a chemical mechanical polishing (CMP), for example. As a result, in the first opening portion 220, the first electrode 11 formed of the copper film 26 (including the seed layer 25) is formed through the manganese oxide layer 27.

Further, the manganese oxide layer 27 formed on the sidewall of the first opening portion 220 serves as the diffusion prevention layer 31 for preventing copper from diffusing. Therefore, the manganese oxide layer 27 serving as the diffusion prevention layer 31 exists in a state of a manganese oxide on the sidewall of the first opening portion 220, to maintain a strong bonding.

As a result, the diffusion prevention layer 31 can be formed without using a tantalum-based or titanium-based barrier metal used in related art.

Next, as shown in FIG. 5D, the storage layer 12 is formed on the first electrode 11 and the first insulating film 21. The storage layer 12 is formed of the oxide of metal such as the oxide of tantalum, the oxide of niobium, the oxide of aluminum, the oxide of hafnium, and the oxide of zirconium, or made of the mixed material thereof. It is desirable to set the storage layer 12 to be thin, specifically, 2 nm or less, desirably, 1 nm or less, more desirably, 0.5 nm or less in thickness.

Further, on the storage layer 12, the ion source layer 13 is formed. The ion source layer 13 contains at least one of copper (Cu), silver (Ag), and zinc (Zn) and at least one of chalcogenide elements such as tellurium (Te), selenium (Se), and sulfur (S). For example, CuTe, GeSbTe, CuGeTe, AgGeTe, AgTe, ZnTe, ZnGeTe, CuS, CuGeS, CuSe, CuGeSe, or the like are contained. Further, boron (B), rare-earth elements, or silicon (Si) may be contained.

Accordingly, the ion source layer 13 contains at least one of the elements of Cu, Ag, and Zn. That is, the ion source layer 13 serves as a layer that supplies ions of at least one of Cu, Ag, and Zn to the storage layer 12 or receives the ions supplied to the storage layer 12.

Next, as shown in FIG. 5E, on the ion source layer 13, the second insulating film 230 is formed. Then, by the lithography technique or the etching technique, in the second insulating film 230, the second opening portion 24 that reaches the ion source layer 13 is formed at a position opposed to the first electrode 11. The second insulating film 230 can be made of a material similar to that capable of being used as the first insulating film 21.

Through the second opening portion 24, the second electrode 14 is formed on the ion source layer 13 above the first electrode 11. The second electrode 14 can be made of a conductive material similar to that of the first electrode 11.

In this way, the semiconductor storage device 1 of the resistance change type is structured.

In the method of manufacturing the semiconductor storage device 1, the diffusion prevention layer 31 of the semiconductor storage device 1 is formed of the manganese oxide. Therefore, even when a high electric field is applied to the diffusion prevention layer 31, manganese is prevented from diffusing in the storage layer 12 or the ion source layer 13. Therefore, the performance degradation of the semiconductor storage device 1 can be suppressed, and there is an advantage in that the high-performance semiconductor storage device of the resistance change type can be provided.

### 6. Sixth Embodiment

### One Example of Method of Manufacturing Semiconductor Storage Device

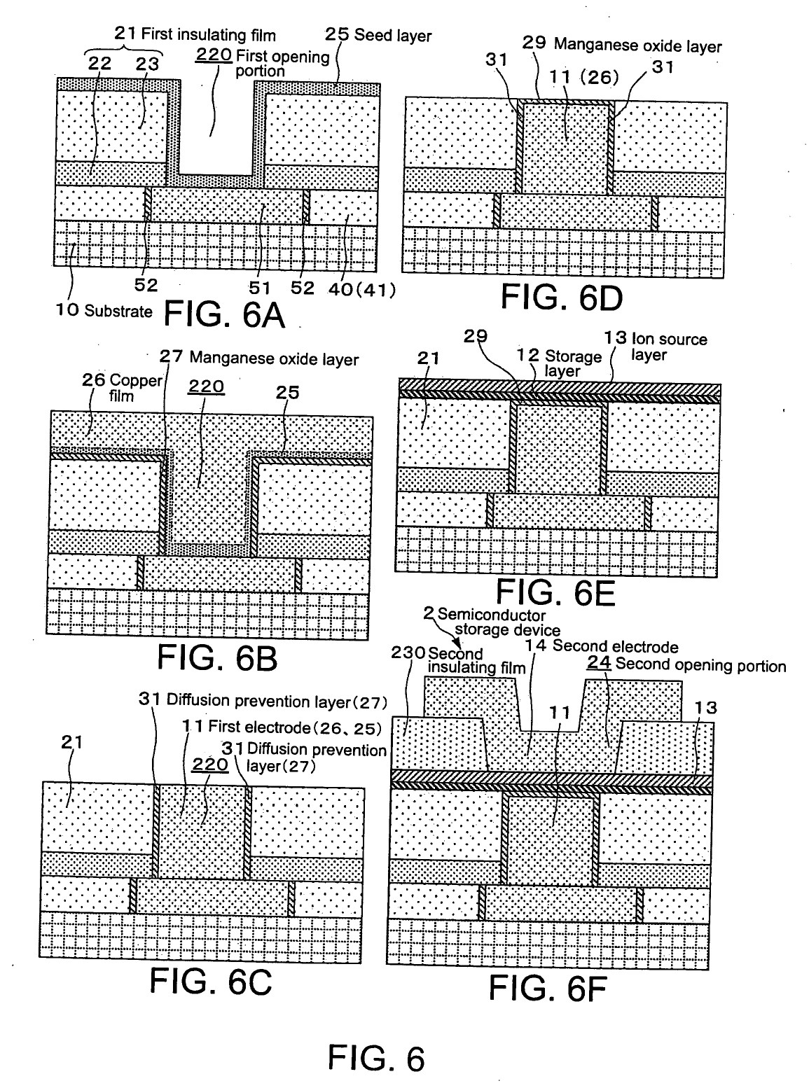

A description will be given on an example of a method of manufacturing a semiconductor storage device according to a sixth embodiment of the present invention, with reference to manufacturing-process cross-sectional views of FIGS. 6A to 6F. FIGS. 6A to 6F show a method of manufacturing the semiconductor storage device 2 described above with reference to FIG. 2.

As shown in FIG. 6A, the first wiring 51 is formed in, e.g., the insulating film 41 in the uppermost layer of the insulating film 40 formed on the substrate 10. The first wiring 51 is formed of a copper wiring, for example. On each of side portions of the first wiring 51, the diffusion prevention layer 52 is formed.

On the insulating film 40, the first insulating film 21 that covers the first wiring 51 is formed. The first insulating film 21 is formed of the laminated films of the silicon carbon nitride film 22 and the silicon oxide (TEOS) film 23, for example. In addition to the silicon oxide film and the silicon carbon nitride film, the following films can be used for the first insulating film 21. For example, the inorganic insulating film such as the silicon nitride film, the silicon oxynitride film, the silicon fluoride oxide film, the aluminum oxide film (Al₂O₃), a tantalum oxide (Ta₂O₅), the hafnium oxide (HfO₂), and the zirconium oxide (ZrO₂) can be used. In addition, an insulating film used for a general semiconductor device, e.g., the fluorine-based organic insulating material such as the amorphous fluorine resin and the polyarylether-fluoride-based resin, the aromatic organic insulating material such as polyarylether, poly-para-xylylene, and polyimide, or the like can be used.

In the first insulating film 21, the first opening portion 220 that reaches the first wiring 51 is formed. The first opening portion 220 is formed by the etching process using the resist mask, which is generally performed in the general semiconductor manufacturing process.

Further, on the inner surface of the first opening portion 220, the seed layer 25 formed of a copper-manganese alloy layer is formed.

The seed layer 25 is made of the copper-manganese alloy by the sputtering method, for example. Specifically, the seed layer 25 is formed to have the thickness of 30 nm to 80 nm by the sputtering method using the copper-manganese (Cu—Mn) alloy target containing Mn of about 2 at % to 10 at %, for example.

Next, as shown in FIG. 6B, by the plating method, the copper film 26 is filled in the first opening portion 220 through the seed layer 25, and the copper film 26 is formed on the first insulating film 21.

Subsequently, a heat treatment is performed, with the result that the manganese oxide layer 27 is self-formed on the surface of the seed layer 25 on the first insulating film 21 side. The heat treatment is performed at 300° C. to 400° C., for example. Specifically, for example, the heat treatment is performed at 350° C. for 10 minutes. By performing the heat treatment under the above-mentioned heat treatment conditions, manganese can be suppressed from being deposited on the surface of the copper film 26. Accordingly, manganese (Mn) is left in the copper film 26.

In order to give the manganese oxide layer 27 the oxidation prevention function for copper, the manganese oxide layer only has to have a thickness of 1 nm or more, desirably, 2 nm or more. If the thickness is excessively increased, the volume occupied by the first electrode 11 is reduced, which increases the resistance. Therefore, it is desirable to set the thickness of the manganese oxide layer 27 to 5 nm or less.

Next, as shown in FIG. 6C, the extra copper film 26 (including the seed layer 25) formed on the first insulating film 21 and the manganese oxide layer 27 are removed. The removal process is performed by the chemical mechanical polishing (CMP), for example. As a result, in the first opening portion 220, the first electrode 11 formed of the copper film 26 (including the seed layer 25) is formed through the manganese oxide layer 27.

Further, the manganese oxide layer 27 formed on the sidewall of the first opening portion 220 serves as the diffusion prevention layer 31 for preventing copper from diffusing. Therefore, the manganese oxide layer 27 serving as the diffusion prevention layer 31 exists in a state of the manganese oxide on the sidewall of the first opening portion 220, to maintain a strong bonding.

As a result, the diffusion prevention layer 31 can be formed without using the tantalum-based or titanium-based barrier metal used in related art.

Next, as shown in FIG. 6D, a heat treatment is performed, thereby causing manganese (Mn) that is left in the copper film 26 to deposit on the surface of the first electrode 11 and react with oxygen in an atmosphere, to form a manganese oxide layer 29 on the surface of the first electrode 11. The manganese oxide layer 29 is formed continuously with the diffusion prevention layer 31.

As shown in FIG. 6E, the storage layer 12 is formed on the manganese oxide layer 29 and on the first insulating film 21. The storage layer 12 is formed of the oxide of metal such as the oxide of tantalum, the oxide of niobium, the oxide of aluminum, the oxide of hafnium, and the oxide of zirconium, or made of the mixed material thereof. It is desirable to set the storage layer 12 to be thin, specifically, 2 nm or less, desirably, 1 nm or less, more desirably, 0.5 nm or less in thickness.

Further, on the storage layer 12, the ion source layer 13 is formed. The ion source layer 13 contains at least one of copper (Cu), silver (Ag), and zinc (Zn) and at least one of chalcogenide elements such as tellurium (Te), selenium (Se), and sulfur (S). For example, CuTe, GeSbTe, CuGeTe, AgGeTe, AgTe, ZnTe, ZnGeTe, CuS, CuGeS, CuSe, CuGeSe, or the like are contained. Further, boron (B), rare-earth elements, or silicon (Si) may be contained.

Accordingly, the ion source layer 13 contains at least one of the elements of Cu, Ag, and Zn. That is, the ion source layer 13 serves as a layer that supplies ions of at least one of Cu, Ag, and Zn to the storage layer 12 or receives the ions supplied to the storage layer 12.

Next, as shown in FIG. 6F, on the ion source layer 13, the second insulating film 230 is formed. Then, by the lithography technique or the etching technique, in the second insulating film 230, the second opening portion 24 that reaches the ion source layer 13 is formed at a position opposed to the first electrode 11. The second insulating film 230 can be made of a material similar to that capable of being used as the first insulating film 21.

Through the second opening portion 24, the second electrode 14 is formed on the ion source layer 13 above the first electrode 11. The second electrode 14 can be made of a conductive material similar to that of the first electrode 11.

In this way, the semiconductor storage device 2 of the resistance change type is structured.

In the method of manufacturing the semiconductor storage device 2, the diffusion prevention layer 31 of the semiconductor storage device 2 is formed of the manganese oxide. Therefore, even when a high electric field is applied to the diffusion prevention layer 31, manganese is prevented from diffusing in the storage layer 12 or the ion source layer 13. Therefore, the performance degradation of the semiconductor storage device 2 can be suppressed, and there is an advantage in that the high-performance semiconductor storage device of the resistance change type can be provided.

In addition, the storage layer 12 is formed of the oxide of metal, and therefore contains oxygen. However, by forming the diffusion prevention layer 31 between the surface of the first electrode 11 and the storage layer 12, oxygen can be prevented from diffusing from the storage layer 12 to the first electrode 11 side.

Further, by forming the manganese oxide layer 27 on the sidewall portion of the first electrode 11 by the first heat treatment, the copper film 26 (including the seed layer 25) can be prevented from peeling off when the chemical mechanical polishing is performed subsequently. For this reason, the manganese oxide layer 27 is formed on the sidewall portion of the first electrode 11 by the first heat treatment, and then the chemical mechanical polishing is performed. After that, the manganese oxide layer 29 is formed on the surface of the first electrode 11 by the second heat treatment.

### 7. Seventh Embodiment

### One Example of Method of Manufacturing Semiconductor Storage Device

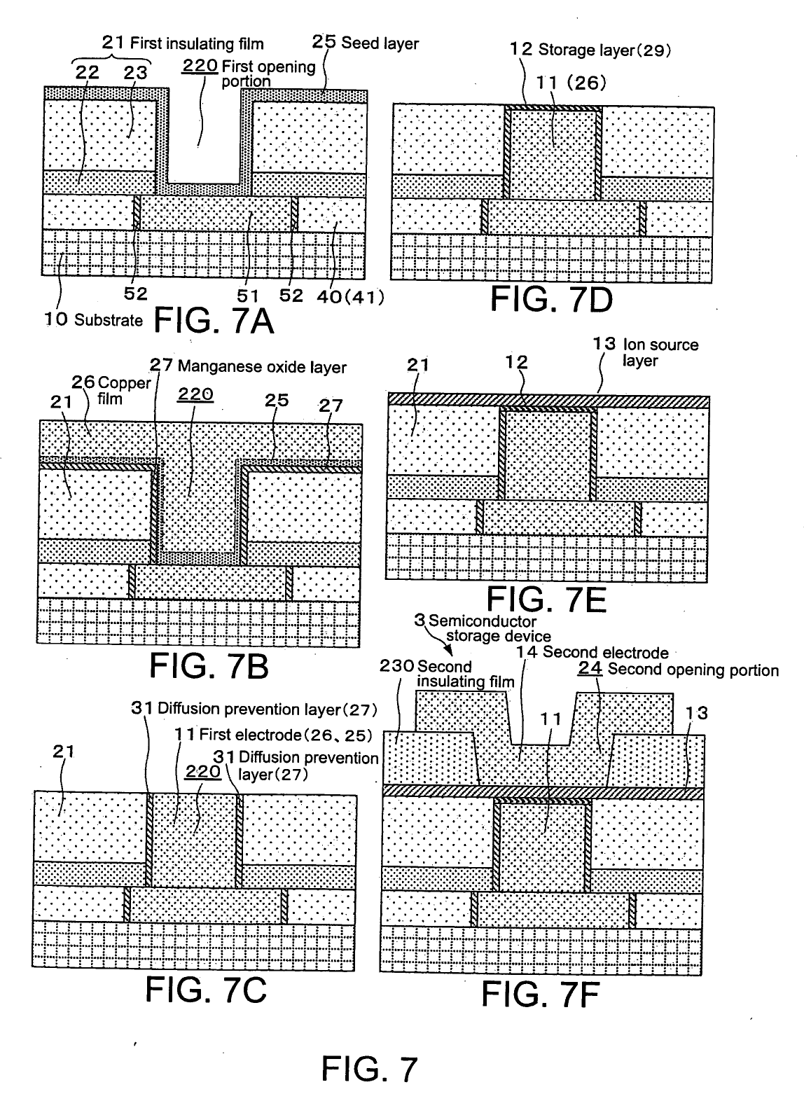

A description will be given on an example of a method of manufacturing a semiconductor storage device according to a seventh embodiment of the present invention, with reference to manufacturing-process cross-sectional views of FIGS. 7A to 7F. FIGS. 7A to 7F show a method of manufacturing the semiconductor storage device 3 described above with reference to FIG. 3. As shown in FIG. 7A, the first wiring 51 is formed in, e.g., the insulating film 41 in the uppermost layer of the insulating film 40 formed on the substrate 10. The first wiring 51 is formed of a copper wiring, for example. On each of side portions of the first wiring 51, the diffusion prevention layer 52 is formed.

On the insulating film 40, the first insulating film 21 that covers the first wiring 51 is formed. The first insulating film 21 is formed of the laminated films of the silicon carbon nitride film 22 and the silicon oxide (TEOS) film 23, for example. In addition to the silicon oxide film and the silicon carbon nitride film, the following films can be used for the first insulating film 21. For example, the inorganic insulating film such as the silicon nitride film, the silicon oxynitride film, the silicon fluoride oxide film, the aluminum oxide film (Al₂O₃), a tantalum oxide (Ta₂O₅), the hafnium oxide (HfO₂), and the zirconium oxide (ZrO₂) can be used. In addition, an insulating film used for a general semiconductor device, e.g., the fluorine-based organic insulating material such as the amorphous fluorine resin and the polyarylether-fluoride-based resin, the aromatic organic insulating material such as polyarylether, poly-para-xylylene, and polyimide, or the like can be used.

In the first insulating film 21, the first opening portion 220 that reaches the first wiring 51 is formed. The first opening portion 220 is formed by the etching process using the resist mask, which is generally performed in the general semiconductor manufacturing process.

Further, on the inner surface of the first opening portion 220, the seed layer 25 formed of a copper-manganese alloy layer is formed.

The seed layer 25 is made of the copper-manganese alloy by the sputtering method, for example. Specifically, the seed layer 25 is formed to have the thickness of 30 nm to 80 nm by the sputtering method using the copper-manganese (Cu—Mn) alloy target containing Mn of about 2 at % to 10 ata, for example.

Next, as shown in FIG. 7B, by the plating method, the copper film 26 is filled in the first opening portion 220 through the seed layer 25, and the copper film 26 is formed on the first insulating film 21.

Subsequently, a heat treatment is performed, with the result that the manganese oxide layer 27 is self-formed on the surface of the seed layer 25 on the first insulating film 21 side. The heat treatment is performed at 300° C. to 400° C., for example. Specifically, for example, the heat treatment is performed at 350° C. for 10 minutes. By performing the heat treatment under the above-mentioned heat treatment conditions, manganese can be suppressed from being deposited on the surface of the copper film 26. Accordingly, manganese (Mn) is left in the copper film 26.

In order to give the manganese oxide layer 27 the oxidation prevention function for copper, the manganese oxide layer only has to have a thickness of 1 nm or more, desirably, 2 nm or more. If the thickness is excessively increased, the volume occupied by the first electrode 11 is reduced, which increases the resistance. Therefore, it is desirable to set the thickness of the manganese oxide layer 27 to 5 nm or less.

Next, as shown in FIG. 7C, the extra copper film 26 (including the seed layer 25) formed on the first insulating film 21 is removed. The removal process is performed by the chemical mechanical polishing (CMP), for example. As a result, in the first opening portion 220, the first electrode 11 formed of the copper film 26 (including the seed layer 25) is formed through the manganese oxide layer 27.

Further, the manganese oxide layer 27 formed on the sidewall of the first opening portion 220 serves as the diffusion prevention layer 31 for preventing copper from diffusing. Therefore, the manganese oxide layer 27 serving as the diffusion prevention layer 31 exists in a state of a manganese oxide on the sidewall of the first opening portion 220, to maintain the strong bonding.

As a result, the diffusion prevention layer 31 can be formed without using the tantalum-based or titanium-based barrier metal used in related art.

Next, as shown in FIG. 7D, the heat treatment is performed, thereby causing manganese (Mn) that is left in the copper film 26 to deposit on the surface of the first electrode 11 and react with oxygen in an atmosphere, to form the manganese oxide layer 29 on the surface of the first electrode 11. The manganese oxide layer 29 has the function of the diffusion prevention layer, and doubles as the storage layer 12. Thus, the storage layer 12 is formed in the manganese oxide layer 29. The storage layer 12 is formed continuously with the manganese oxide layer 27. It is desirable to set the storage layer 12 to be thin, specifically, 2 nm or less in thickness.

As shown in FIG. 7E, on the first insulating film 21 and on the storage layer 12, the ion source layer 13 is formed. The ion source layer 13 contains at least one of copper (Cu), silver (Ag), and zinc (Zn) and at least one of chalcogenide elements such as tellurium (Te), selenium (Se), and sulfur (S). For example, CuTe, GeSbTe, CuGeTe, AgGeTe, AgTe, ZnTe, ZnGeTe, CuS, CuGeS, CuSe, CuGeSe, or the like are contained. Further, boron (B), rare-earth elements, or silicon (Si) may be contained.

Accordingly, the ion source layer 13 contains at least one of the elements of Cu, Ag, and Zn. That is, the ion source layer 13 serves as a layer that supplies ions of at least one of Cu, Ag, and Zn to the storage layer 12 or receives the ions supplied to the storage layer 12.

Next, as shown in FIG. 7F, on the ion source layer 13, the second insulating film 230 is formed. Then, by the lithography technique or the etching technique, in on the second insulating film 230, the second opening portion 24 that reaches the ion source layer 13 is formed at a position opposed to the first electrode 11. The second insulating film 230 can be made of a material similar to that capable of being used as the first insulating film 21.

Through the second opening portion 24, the second electrode 14 is formed on the ion source layer 13 above the first electrode 11. The second electrode 14 can be made of a conductive material similar to that of the first electrode 11.

In this way, the semiconductor storage device 3 of the resistance change type is structured.

In the method of manufacturing the semiconductor storage device 3, the diffusion prevention layer 31 of the semiconductor storage device 3 is formed of the manganese oxide. Therefore, even when a high electric field is applied to the diffusion prevention layer 31, manganese is prevented from diffusing in the ion source layer 13. Therefore, the performance degradation of the semiconductor storage device 3 can be suppressed, and there is an advantage in that the high-performance semiconductor storage device of the resistance change type can be provided.

In addition, the storage layer 12 is made of the manganese oxide. Therefore, even on the side of the surface of the first electrode 11, a diffusion of oxygen into the first electrode 11 can be prevented, and a diffusion of copper in the first electrode 11 to outside can also be prevented.

Further, by forming the manganese oxide layer 27 on the sidewall portion of the first electrode 11 by the first heat treatment, the copper film 26 (including the seed layer 25) can be prevented from peeling off when the chemical mechanical polishing is performed subsequently. For this reason, the manganese oxide layer 27 is formed on the sidewall portion of the first electrode 11 by the first heat treatment, and then the chemical mechanical polishing is performed. After that, the manganese oxide layer 29 is formed on the surface of the first electrode 11 by the second heat treatment.

In addition, because the manganese oxide layer 29 formed on the first electrode 11 functions as the diffusion prevention layer and the storage layer 12, a process of forming the storage layer 12 can be eliminated, with the result that a cost reduction can be expected.

### 8. Eighth Embodiment

### One Example of Method of Manufacturing Semiconductor Storage Device

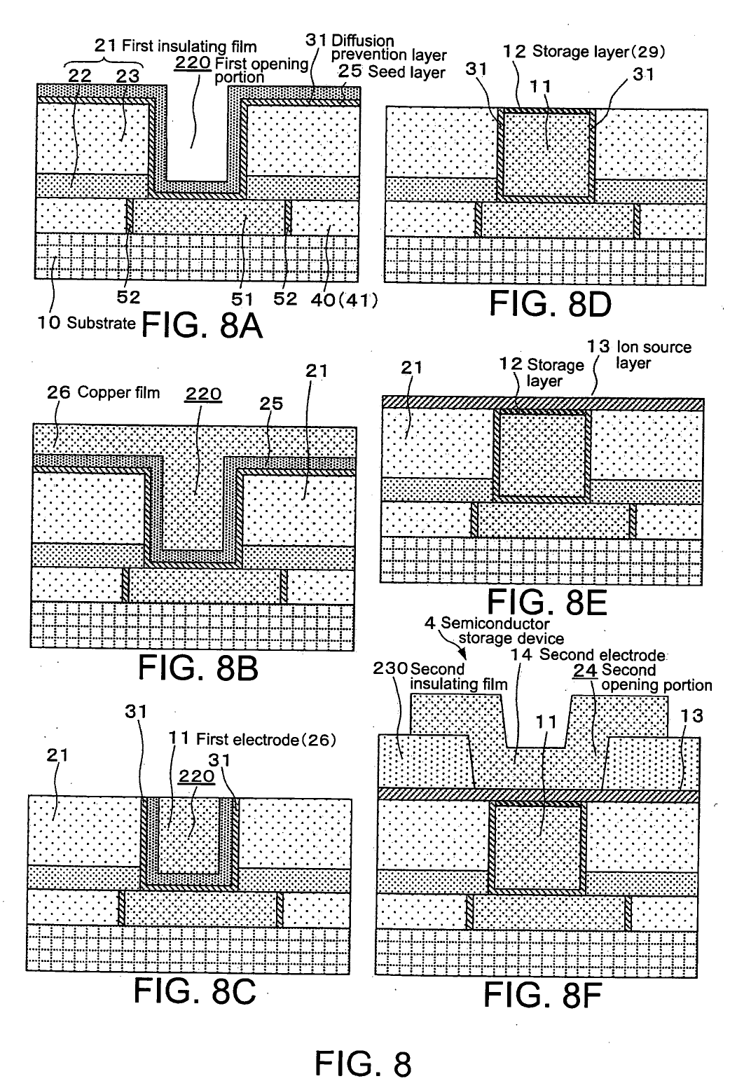

A description will be given on an example of a method of manufacturing a semiconductor storage device according to an eighth embodiment of the present invention, with reference to manufacturing-process cross-sectional views of FIGS. 8A to F. FIGS. 8A to 8F show a method of manufacturing the semiconductor storage device 4 described above with reference to FIG. 4.

As shown in FIG. 8A, the first wiring 51 is formed in, e.g., the insulating film 41 in the uppermost layer of the insulating film 40 formed on the substrate 10. The first wiring 51 is formed of a copper wiring, for example. On each of side portions of the first wiring 51, the diffusion prevention layer 52 is formed.

On the insulating film 40, the first insulating film 21 that covers the first wiring 51 is formed. The first insulating film 21 is formed of the laminated films of the silicon carbon nitride film 22 and the silicon oxide (TEOS) film 23, for example. In addition to the silicon oxide film and the silicon carbon nitride film, the following films can be used for the first insulating film 21. For example, the inorganic insulating film such as the silicon nitride film, the silicon oxynitride film, the silicon fluoride oxide film, the aluminum oxide film (Al₂O₃), a tantalum oxide (Ta₂O₅), the hafnium oxide (HfO₂), and the zirconium oxide (ZrO₂) can be used. In addition, an insulating film used for a general semiconductor device, e.g., the fluorine-based organic insulating material such as the amorphous fluorine resin and the polyarylether-fluoride-based resin, the aromatic organic insulating material such as polyarylether, poly-para-xylylene, and polyimide, or the like can be used.

In the first insulating film 21, the first opening portion 220 that reaches the first wiring 51 is formed. The first opening portion 220 is formed by the etching process using the resist mask, which is generally performed in the general semiconductor manufacturing process.

Next, the diffusion prevention layer 31 is formed in the first opening portion 22. The diffusion prevention layer 31 may be formed of the tungsten-based barrier metal layer such as tungsten (W) and a tungsten nitride (WN), the zirconium-based barrier metal layer such as zirconium and a zirconium nitride, the hafnium-based barrier metal layer such as hafnium and a hafnium nitride, or the ruthenium-based barrier metal layer such as ruthenium (RuN) or a ruthenium nitride (RuN). It should be noted that, for the barrier metal layer, the tantalum-based material such as tantalum and a tantalum nitride or the titanium-based material such as titanium and a titanium nitride is not used. The diffusion prevention layer 31 is formed by a sputtering, a chemical vapor deposition (CVD), or the like.

Subsequently, on the surface of the diffusion prevention layer 31, the seed layer 25 formed of the copper-manganese alloy layer is formed.

The seed layer 25 is made of the copper-manganese alloy by the sputtering method, for example. Specifically, the seed layer 25 is formed to have the thickness of 30 nm to 80 nm by the sputtering method using the copper-manganese (Cu—Mn) alloy target containing Mn of about 2 at % to 10 at %, for example.

Next, as shown in FIG. 8B, by a plating method, the copper film 26 is filled in the first opening portion 220 through the seed layer 25, and the copper film 26 is formed on the first insulating film 21.

Next, as shown in FIG. 8C, the extra copper film 26 formed on the first insulating film 21 is removed. The removal process is performed by the chemical mechanical polishing (CMP), for example. As a result, in the first opening portion 220, the first electrode 11 formed of the copper film 26 (including the seed layer 25) is formed through the diffusion prevention layer 31.

Further, the diffusion prevention layer 31 formed on the sidewall of the first opening portion 220 prevents the diffusion of the copper.

As a result, the diffusion prevention layer 31 can be formed without using a tantalum-based or titanium-based barrier metal used in related art.

Next, as shown in FIG. 8D, the heat treatment is performed, thereby causing manganese (Mn) in the first electrode 11 to deposit on the surface of the first electrode 11 and react with oxygen in an atmosphere, to cause the manganese oxide layer 29 to be self-formed on the surface of the first electrode 11. The heat treatment is performed at 300° C. to 400° C., for example. Specifically, the heat treatment is performed at 350° C. for 30 minutes, for example. The manganese oxide layer 29 has the function of the diffusion prevention layer, and doubles as the storage layer 12. Thus, the storage layer 12 is formed in the manganese oxide layer 29. The storage layer 12 is formed in connection with the diffusion prevention layer 31. It is desirable to set the storage layer 12 to be thin, specifically, 2 nm or less in thickness.

As shown in FIG. 8E, on the first insulating film 21 and on the storage layer 12, the ion source layer 13 is formed. The ion source layer 13 contains at least one of copper (Cu), silver (Ag), and zinc (Zn) and at least one of chalcogenide elements such as tellurium (Te), selenium (Se), and sulfur (S). For example, CuTe, GeSbTe, CuGeTe, AgGeTe, AgTe, ZnTe, ZnGeTe, CuS, CuGeS, CuSe, CuGeSe, or the like are contained. Further, boron (B), rare-earth elements, or silicon (Si) may be contained.

Accordingly, the ion source layer 13 contains at least one of the elements of Cu, Ag, and Zn. That is, the ion source layer 13 serves as a layer that supplies ions of at least one of Cu, Ag, and Zn to the storage layer 12 or receives the ions supplied to the storage layer 12.

Next, as shown in FIG. 8F, on the ion source layer 13, the second insulating film 230 is formed. Then, by the lithography technique or the etching technique, the second opening portion 24 that reaches the ion source layer 13 is formed in a position on the second insulating film 230, which is opposed to the first electrode 11. The second insulating film 230 can be made of a material similar to that capable of being used as the first insulating film 21.

Through the second opening portion 24, the second electrode 14 is formed on the ion source layer 13 above the first electrode 11. The second electrode 14 can be made of a conductive material similar to that of the first electrode 11.

In this way, the semiconductor storage device 4 of the resistance change type is structured.

In the method of manufacturing the semiconductor storage device 4, the diffusion prevention layer 31 is formed of the tungsten-based barrier metal layer, the zirconium-based barrier metal layer, the hafnium-based barrier metal layer, or the ruthenium-based barrier metal layer. Therefore, even when a high electric field is applied to the diffusion prevention layer 31, metal in the diffusion prevention layer 31 is prevented from diffusing in the ion source layer 13. Therefore, the performance degradation of the semiconductor storage device 4 can be suppressed, and there is an advantage in that the high-performance semiconductor storage device of the resistance change type can be provided.

In addition, the storage layer 12 is formed of the manganese oxide. Therefore, even on the side of the surface of the first electrode 11, a diffusion of oxygen into the first electrode 11 can be prevented, and a diffusion of copper in the first electrode 11 to outside can also be prevented.

Further, by forming the diffusion prevention layer 31 that is the tungsten-based or ruthenium-based barrier metal layer on the sidewall portion of the first electrode 11, the copper film 26 (including the seed layer 25) can be prevented from peeling off when the chemical mechanical polishing is performed subsequently.

In addition, because the manganese oxide layer 29 formed on the first electrode 11 functions as the diffusion prevention layer and the storage layer 12, a process of forming the storage layer 12 can be eliminated, with the result that a cost reduction can be expected.

The semiconductor storage devices 1 to 4 described above can structure a storage device (memory) by being formed in a matrix pattern, for example.

Specifically, for example, the second electrode 14 is formed in common with a memory cell in a row direction, and a wiring connected to the first electrode 11 is formed in common with a memory cell in a column direction. By selecting the wiring and the second electrode to which a potential is applied and a current is caused to flow, a memory cell on which recording is to be performed is selected. A current is caused to flow into the semiconductor storage devices 1 to 4 including the selected memory cell, with the result that the information can be recorded, or the recorded information can be deleted.

In addition, the semiconductor storage devices 1 to 4 enable easy, stable information recording and information reading and have excellent characteristics particularly in long-term data retention stability in a high-temperature environment.

Further, the semiconductor storage devices 1 to 4 make it easy to record the information or read the recorded information, even when they are miniaturized.

Thus, by structuring the storage device with the use of the semiconductor storage devices 1 to 4, the integration (high densification) or the size reduction of the storage device can be realized.

The present application contains subject matter related to that disclosed in Japanese Priority Patent Application JP 2009-017471 filed in the Japan Patent Office on Jan. 29, 2009, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor storage device, comprising:
a first electrode formed by being embedded in an insulating film formed on a substrate;
a second electrode formed to be opposed to the first electrode;
a storage layer formed between the first electrode and the second electrode, the storage layer being on a side of the first electrode;
an ion source layer formed between the storage layer and the second electrode; and
a diffusion prevention layer formed of a manganese oxide layer between the insulating film and the first electrode.

2. The semiconductor storage device according to claim 1,
wherein the diffusion prevention layer formed of the manganese oxide layer is continuously formed in an interface between the first electrode and the storage layer.

3. The semiconductor storage device according to claim 1,
wherein the storage layer is formed of a metal oxide film.

4. The semiconductor storage device according to claim 1,
wherein the storage layer is formed in an interface between the first electrode and the ion source layer and is formed of the manganese oxide layer that is continuous with the diffusion prevention layer.

5. The semiconductor storage device according to claim 1,
wherein the diffusion prevention layer is formed of one of a tungsten layer, a tungsten nitride layer, a zirconium layer, a zirconium nitride layer, a hafnium layer, a hafnium nitride layer, a ruthenium layer, and a ruthenium nitride layer, instead of the manganese oxide layer.

6. A semiconductor storage device, comprising:
a first electrode formed by being embedded in an insulating film formed on a substrate;
a second electrode formed to be opposed to the first electrode;
a storage layer formed of a manganese oxide layer between the first electrode and the second electrode, the storage layer being on a side of the first electrode; and
an ion source layer formed between the storage layer and the second electrode; and
a diffusion prevention layer formed of at least one of a tungsten layer, a tungsten nitride layer, a ruthenium layer, and a ruthenium nitride layer, the diffusion prevention layer being formed between the insulating film and the first electrode and connected with the storage layer.

7. A method of manufacturing a semiconductor storage device, comprising:
forming an opening portion in an insulating film formed on a substrate;
forming a seed layer on an inner surface of the opening portion, the seed layer being formed of a copper-manganese alloy layer;
embedding a copper film in the opening portion through the seed layer and forming the copper film on the insulating film;
forming a manganese oxide layer in a surface of the seed layer on a side of the insulating film by a heat treatment;
forming a first electrode in the opening portion through a diffusion prevention layer by removing the copper film redundant on the insulating film and the manganese oxide layer formed on the copper film, the first electrode being formed of the copper film, the diffusion prevention layer being formed of the manganese oxide layer;
forming a storage layer on the first electrode and the insulating layer;
forming an ion source layer on the storage layer; and
forming a second electrode on the ion source layer.

8. A method of manufacturing a semiconductor storage device, comprising:
forming an opening portion in an insulating film formed on a substrate;
forming a seed layer on an inner surface of the opening portion, the seed layer being formed of a copper-manganese alloy layer;
embedding a copper film in the opening portion through the seed layer and forming the copper film on the insulating film;
forming a manganese oxide layer in a surface of the seed layer on a side of the insulating film by a heat treatment;
forming a first electrode in the opening portion through a diffusion prevention layer by removing the copper film redundant on the insulating film and the manganese oxide layer formed on the copper film, the first electrode being formed of the copper film, the diffusion prevention layer being formed of the manganese oxide layer;
forming a manganese oxide layer on a surface of the first electrode by the heat treatment;
forming a storage layer on the insulating film and on the first electrode through the manganese oxide layer formed on the surface of the first electrode;
forming an ion source layer on the storage layer; and
forming a second electrode on the ion source layer.

9. A method of manufacturing a semiconductor storage device, comprising:
forming an opening portion in an insulating film formed on a substrate;
forming a seed layer on an inner surface of the opening portion, the seed layer being formed of a copper-manganese alloy layer;
embedding a copper film in the opening portion through the seed layer and forming the copper film on the insulating film;
forming a manganese oxide layer in a surface of the seed layer on a side of the insulating film by a heat treatment;
forming a first electrode in the opening portion through a diffusion prevention layer by removing the copper film redundant on the insulating film and the manganese oxide layer formed on the copper film, the first electrode being formed of the copper film, the diffusion prevention layer being formed of the manganese oxide layer;
forming a storage layer on a surface of the first electrode by the heat treatment, the storage layer being formed of a manganese oxide layer;
forming an ion source layer on the storage layer; and
forming a second electrode on the ion source layer.

10. A method of manufacturing a semiconductor storage device, comprising:
forming an opening portion in an insulating film formed on a substrate;
forming a diffusion prevention layer on an inner surface of the opening portion, the diffusion prevention layer being formed of at least one of a tungsten layer, a tungsten nitride layer, a zirconium layer, a zirconium nitride layer, a hafnium layer, a hafnium nitride layer, a ruthenium layer, and a ruthenium nitride layer;
forming a seed layer on the inner surface of the opening portion through the diffusion prevention layer, the seed layer being formed of a copper-manganese alloy layer;
embedding a copper film in the opening portion through the seed layer and forming the copper film on the insulating film;
forming a first electrode in the opening portion through the diffusion prevention layer by removing the copper film, the seed layer, and the diffusion prevention layer that are redundant on the insulating film, the first electrode being formed of the seed layer and the copper film;
forming a storage layer on a surface of the first electrode by a heat treatment, the storage layer being formed of a manganese oxide layer, the manganese oxide layer being connected with the diffusion prevention layer;
forming an ion source layer on the insulating film and on the storage layer; and
forming a second electrode on the ion source layer.
